(19) United States
(12) Patent Application Publication
(10) Pub. No.: US 2024/0079469 A1
(43) Pub. Date: Mar. 7, 2024

(54) SEMICONDUCTOR DEVICE AND METHOD FOR MANUFACTURING SEMICONDUCTOR DEVICE

(71) Applicant: ROHM CO., LTD., Kyoto-shi (JP)

(72) Inventors: Masaya UENO, Kyoto-shi (JP); Sawa HARUYAMA, Kyoto-shi (JP); Masaya SAITO, Kyoto-shi (JP)

(73) Assignee: ROHM CO., LTD., Kyoto-shi (JP)

(21) Appl. No.: 18/481,258

(22) Filed: Oct. 5, 2023

Related U.S. Application Data
(63) Continuation of application No. PCT/JP2022/012074, filed on Mar. 16, 2022.

(30) Foreign Application Priority Data
Apr. 5, 2021 (JP) 2021-064154

(51) Int. Cl. H01L 29/47; H01L 21/02; H01L 29/66; H01L 29/872

(52) U.S. Cl. CPC H01L 29/47; H01L 21/02529; H01L 29/66143; H01L 29/872

(57) ABSTRACT

A semiconductor device includes a semiconductor layer, a Schottky electrode that is formed at a first surface of the semiconductor layer and that forms a Schottky junction Sj between the semiconductor layer and the Schottky electrode, and the Schottky electrode has a first portion that is selectively formed near the first surface of the semiconductor layer in a thickness direction of the Schottky electrode and that is made of Ti containing oxygen. The Schottky electrode may have a second portion that is formed on the first portion and that is made of Ti and N.

### CROSS-REFERENCE TO RELATED APPLICATIONS

The present application is a bypass continuation application of International Patent Application No. PCT/JP2022/012074, filed on Mar. 16, 2022, which corresponds to Japanese Patent Application No. 2021-064154 filed on Apr. 5, 2021 with the Japan Patent Office, and the entire disclosure of this application is incorporated herein by reference.

### TECHNICAL FIELD

The present disclosure relates to a semiconductor device including a Schottky barrier diode and a method for manufacturing the semiconductor device.

### BACKGROUND ART

Japanese Patent Application Publication No. 2010-225877 discloses an SiC semiconductor device that is composed of an n⁺-type substrate made of silicon carbide, an n⁻-type drift layer that is formed at a principal front surface of the substrate and that is made of silicon carbide having a dopant concentration lower than the substrate, an SBD formed at cell portions of both the n⁺-type substrates and the n⁻-type drift layer, and a termination structure formed in outer peripheral regions of both the n⁺-type substrate and the n⁻-type drift layer. The SBD includes a Schottky electrode. The Schottky electrode has an oxide layer made of molybdenum oxide at its part brought into direct contact with SiC, a metal layer that is formed on the oxide layer and that is made of molybdenum, and an electrode layer for joining that is used to make electrical connection by means of a wire bonding or the like.

### BRIEF DESCRIPTION OF DRAWINGS

FIG. 1 is a schematic plan view of a Schottky barrier diode according to a first preferred embodiment of the present disclosure.

FIG. 2 is a cross-sectional view along line II-II shown in FIG. 1.

FIG. 3 is a plan view showing a state in which a structure, which is higher than a first principal surface of a semiconductor layer, of the Schottky barrier diode has been removed.

FIG. 4 is an enlarged view of a part surrounded by alternate long and two short dashed line IV of FIG. 2.

FIG. 5 is an enlarged view of a part surrounded by alternate long and two short dashed line V of FIG. 2.

FIG. 6 is a view showing an analysis result of constituent elements of both a Schottky electrode and an anode electrode of the Schottky barrier diode.

FIG. 7 is a flowchart of a manufacturing process of the Schottky barrier diode.

FIG. 8A and FIG. 8B are views each of which shows a part of the manufacturing process of the Schottky barrier diode.

FIG. 9A and FIG. 9B are views showing steps subsequent to the steps of FIG. 8A and FIG. 8B, respectively.

FIG. 10A and FIG. 10B are views showing steps subsequent to the steps of FIG. 9A and FIG. 9B, respectively.

FIG. 11A and FIG. 11B are views showing steps subsequent to the steps of FIG. 10A and FIG. 10B, respectively.

FIG. 12A and FIG. 12B are views showing steps subsequent to the steps of FIG. 11A and FIG. 11B, respectively.

FIG. 13A and FIG. 13B are views showing steps subsequent to the steps of FIG. 12A and FIG. 12B, respectively.

FIG. 14A and FIG. 14B are views showing steps subsequent to the steps of FIG. 13A and FIG. 13B, respectively.

FIG. 15A and FIG. 15B are views showing steps subsequent to the steps of FIG. 14A and FIG. 14B, respectively.

FIG. 16 is a view showing an analysis result of constituent elements of both a Schottky electrode and an anode electrode of the Schottky barrier diode according to sample 2.

FIG. 17A and FIG. 17B show I-V curves of the Schottky barrier diode according to samples 1 to 3.

FIG. 18A and FIG. 18B show I-V curves of the Schottky barrier diode according to samples 4 and 5.

FIG. 19 is a schematic cross-sectional view of a Schottky barrier diode according to a second preferred embodiment of the present disclosure.

FIG. 20 is a plan view showing a state in which a structure, which is higher than a first principal surface of a semiconductor layer, of the Schottky barrier diode of FIG. 19 has been removed.

FIG. 21 is an enlarged view of a part surrounded by alternate long and two short dashed line XXI of FIG. 19.

FIG. 22A is a circuit diagram for describing a voltage drop around an inner impurity region included in the Schottky barrier diode of FIG. 19.

FIG. 22B is a cross-sectional view for describing a voltage drop around the inner impurity region.

### DESCRIPTION OF EMBODIMENTS

First, a preferred embodiment of the present disclosure will be described in an itemized form.

A semiconductor device according to a preferred embodiment of the present disclosure includes a semiconductor layer and a Schottky electrode that is formed at a first surface of the semiconductor layer and that forms a Schottky junction between the semiconductor layer and the Schottky electrode, in which the Schottky electrode has a first portion that is selectively formed near the first surface of the semiconductor layer in a thickness direction of the Schottky electrode and that is made of Ti containing oxygen.

With this configuration, the Schottky electrode has the first portion that is selectively formed near the first surface of the semiconductor layer in the thickness direction of the Schottky electrode. This first portion is made of Ti that contains oxygen. This makes it possible to reduce the forward voltage of the Schottky electrode.

In the semiconductor device according to a preferred embodiment of the present disclosure, the Schottky electrode may have a second portion that is formed on the first portion and that is made of Ti and N.

In the semiconductor device according to a preferred embodiment of the present disclosure, an oxygen concentration near the Schottky junction portion may be higher than both an oxygen concentration in the vicinity of an interface between the first portion and the second portion and an average oxygen concentration of the semiconductor layer.

In the semiconductor device according to a preferred embodiment of the present disclosure, when an analysis is made in a first direction from the Schottky electrode toward the semiconductor layer according to a predetermined quantitative-analysis method, an oxygen concentration profile corresponding to an inside of the first portion may have a peak at a position closer to a boundary portion between the first portion and the semiconductor layer than a center position of the first portion in the first direction.

With this configuration, the oxygen concentration near the boundary portion between the first portion of the Schottky electrode and the semiconductor layer becomes high, thereby making it possible to further reduce the forward voltage.

In the semiconductor device according to a preferred embodiment of the present disclosure, a concentration at the peak of the oxygen concentration profile may be not less than 2.0 atm % and not more than 10.0 atm %.

The semiconductor device according to a preferred embodiment of the present disclosure may include an insulation layer that is formed at the first surface of the semiconductor layer and that has an opening from which the first surface is partially exposed, and the Schottky electrode may include a first covering portion that covers the first surface of the semiconductor layer in the opening of the insulation layer and a second covering portion that is formed outside the opening of the insulation layer and that covers the insulation layer, and the first portion may selectively contain oxygen in the first covering portion of the Schottky electrode, and may not contain oxygen in the second covering portion.

In the semiconductor device according to a preferred embodiment of the present disclosure, the semiconductor layer may not contain oxygen near the first surface in the Schottky junction portion.

With this configuration, it is possible to restrain an increase in resistance of a part, which is contiguous to the first portion of the Schottky electrode, of the semiconductor layer, thereby making it possible to efficiently pass a forward current.

The semiconductor device according to a preferred embodiment of the present disclosure may include a front surface electrode that is formed on the Schottky electrode and that is made of an Al alloy or Al.

In the semiconductor device according to a preferred embodiment of the present disclosure, the Al alloy may include at least one among an AlCu alloy, an AlSi alloy, and an AlSiCu alloy.

In the semiconductor device according to a preferred embodiment of the present disclosure, the semiconductor layer may include a first conductivity type semiconductor layer, and the semiconductor device may further include a second conductivity type impurity region that is selectively formed at the first surface of the semiconductor layer so as to be contiguous to the Schottky electrode and that makes a p-n junction between the semiconductor layer and the second conductivity type impurity region.

With this configuration, it is possible to reduce a reverse leakage current by means of a depletion layer that spreads from the p-n junction between the semiconductor layer and the impurity region.

The semiconductor device according to a preferred embodiment of the present disclosure may further include a lattice defect region that is selectively formed at the first surface of the semiconductor layer so as to be contiguous to the Schottky electrode and that has lattice defects more than the semiconductor layer, in which the impurity region may include a first region formed inside the lattice defect region so as to be contiguous to the lattice defect region.

With this configuration, the lattice defect region having lattice defects more than the semiconductor layer is selectively formed. This makes it possible to make an electric current flowing to the lattice defect region smaller than an electric current flowing to the Schottky junction portion.

Additionally, the first region of the impurity region is formed inside the lattice defect region. A voltage drop of a part, which is placed near the lattice defect region, of the semiconductor layer becomes smaller than a voltage drop of a part, which is placed near the Schottky junction portion, of the semiconductor layer. The first region is formed inside the lattice defect region, and therefore a voltage drop caused by the semiconductor layer is also reduced in an area around the inner impurity region. Therefore, it is possible to sufficiently secure a potential difference in a p-n boundary of the p-n junction portion between the first region and the semiconductor layer. As a result, it is possible to improve surge withstand capability.

In the semiconductor device according to a preferred embodiment of the present disclosure, the first conductivity type may be an n-type, and the second conductivity type may be a p-type.

In the semiconductor device according to a preferred embodiment of the present disclosure, the semiconductor layer may include an SiC semiconductor layer.

A method for manufacturing a semiconductor device according to a preferred embodiment of the present disclosure includes a step of introducing oxygen into the first surface of the semiconductor layer having a first surface, a step of forming a Schottky electrode having a first portion made of Ti that is contiguous to the first surface of the semiconductor layer by depositing Ti on the first surface of the semiconductor layer, and a step of diffusing the oxygen introduced into the semiconductor layer into the first portion of the Schottky electrode by annealing treatment.

According to this method, oxygen is contained in the first portion of the Schottky electrode by the diffusion of oxygen. This makes it possible to provide a semiconductor device capable of reducing the forward voltage of the Schottky electrode.

The method for manufacturing a semiconductor device according to a preferred embodiment of the present disclosure may further include a step of washing the first surface of the semiconductor layer by means of a chemical liquid, in which the step of introducing oxygen may include a step of introducing oxygen into the semiconductor layer by irradiating oxygen plasma toward the first surface of the semiconductor layer washed by the chemical liquid.

According to this method, the step of irradiating oxygen plasma is performed later than the step of washing the first surface of the semiconductor layer. Therefore, it is possible to prevent the oxygen that has been introduced into the semiconductor layer by means of irradiation from being removed in the washing step.

In the method for manufacturing a semiconductor device according to a preferred embodiment of the present disclosure, the step of forming the Schottky electrode may include a step of forming a second portion made of Ti and N on the first portion by additionally depositing Ti in an N₂ atmosphere after the first portion is formed.

### First Preferred Embodiment

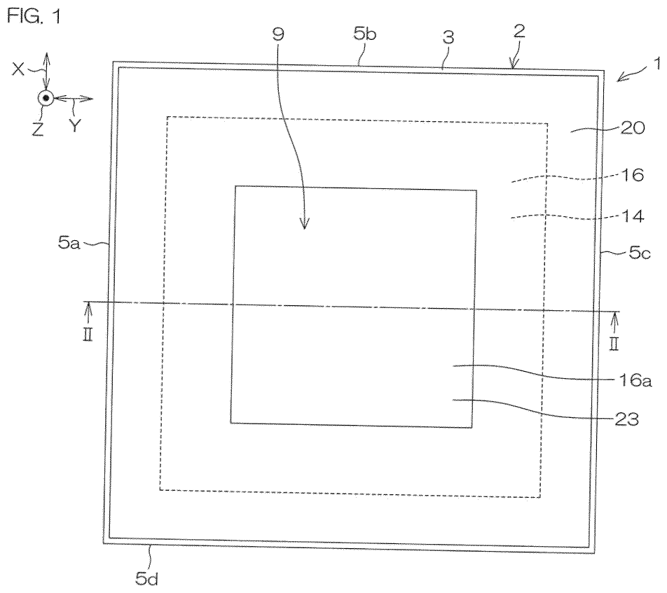

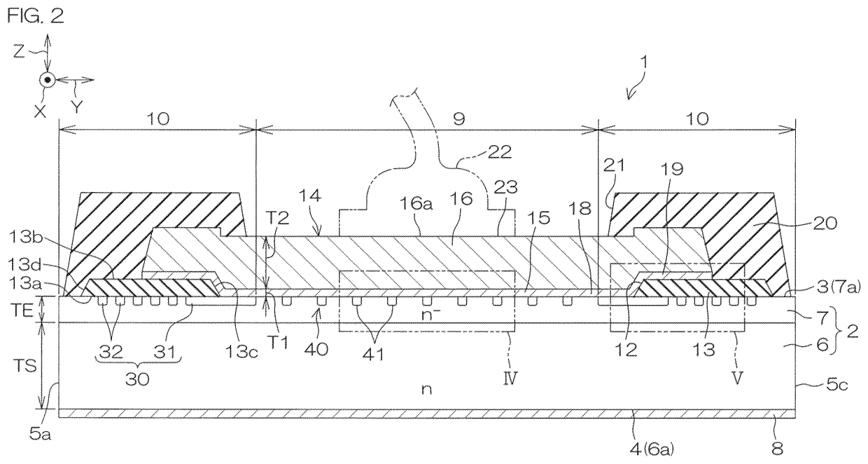

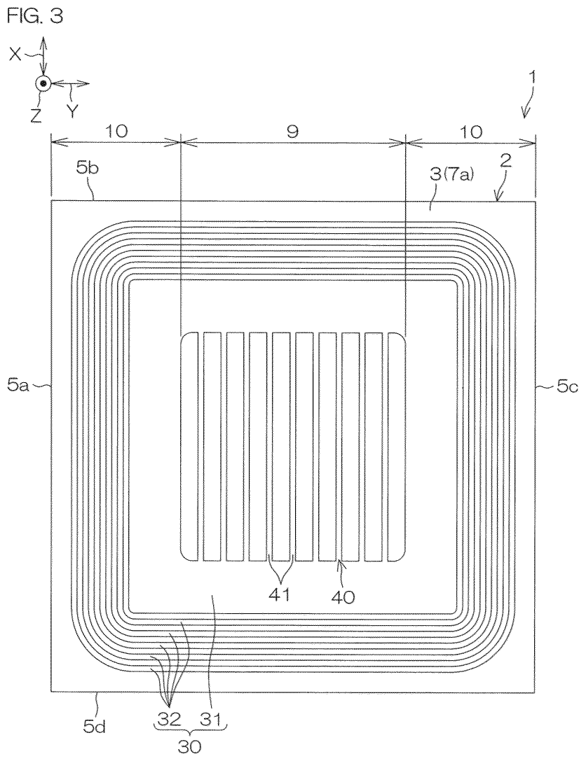

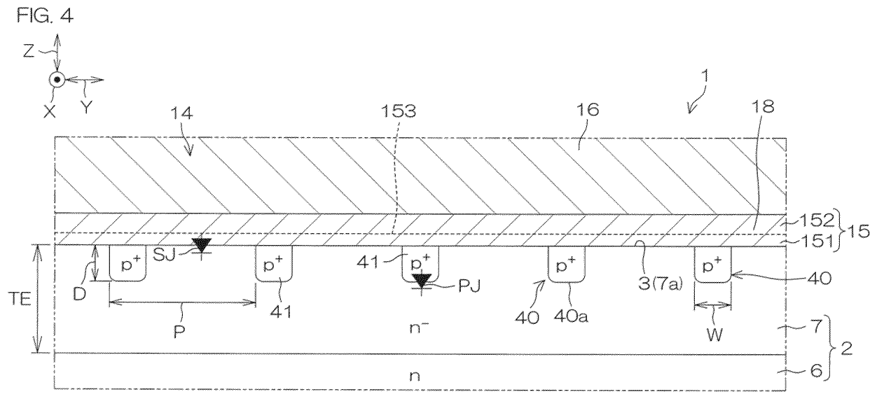

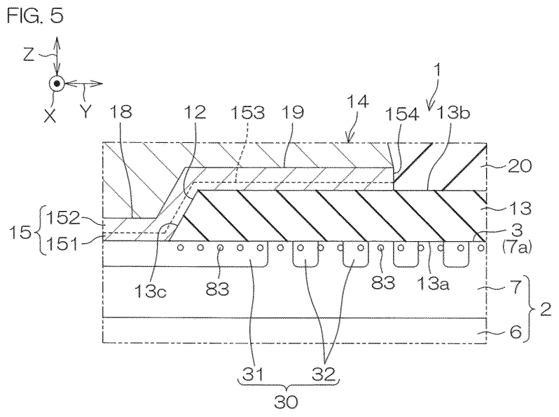

FIG. 1 is a schematic plan view of a Schottky barrier diode 1 according to a first preferred embodiment of the present disclosure. FIG. 2 is a cross-sectional view along line II-II shown in FIG. 1. FIG. 3 is a plan view showing a state in which a structure, which is higher than a first principal surface 3 of a semiconductor layer 2, of the Schottky barrier diode 1 has been removed. FIG. 4 is an enlarged view of a part surrounded by alternate long and two short dashed line IV of FIG. 2. FIG. 5 is an enlarged view of a part surrounded by alternate long and two short dashed line V of FIG. 2.

Referring to FIG. 1, the Schottky barrier diode 1 is a Schottky barrier diode in which 4H—SiC is employed (for example, the insulation breakdown electric-field is about 2.8 MV/cm, and the wide bandgap semiconductor has a bandgap width of about 3.26 eV). The Schottky barrier diode 1 has, for example, a square chip shape in a plan view. The length of each side of the chip-shaped Schottky barrier diode 1 may be, for example, not less than 0.5 mm and not more than 20 mm. In other words, the chip size of the Schottky barrier diode 1 may be, for example, not less than 0.5 mm/□ and not more than 20 mm/□.

The Schottky barrier diode 1 includes a semiconductor layer 2 formed so as to have a rectangular-parallelepiped chip shape. The semiconductor layer 2 may include, for example, an SiC semiconductor layer. Preferably, the off-angle of the semiconductor layer 2 is equal to or less than, for example, 4°. The semiconductor layer 2 has a first principal surface 3 and a second principal surface 4 (see FIG. 2) on the side opposite to the first principal surface 3 in a thickness direction. The semiconductor layer 2 has side surfaces 5a, 5b, 5c, and 5d that connect the first principal surface 3 and the second principal surface 4 together. The first principal surface 3 and the second principal surface 4 are each formed in a quadrangular shape (in the preferred embodiment, square shape) in a plan view seen from these normal directions (third direction Z) (hereinafter, referred to simply as a “plan view”).

In the preferred embodiment, the side surface 5a and the side surface 5c extend along a first direction X, and face each other in a second direction Y intersecting the first direction X. In the preferred embodiment, the side surface 5b and the side surface 5d extend along the second direction Y, face each other in the first direction. More specifically, the second direction Y may be a direction perpendicular to the first direction X.

Referring to FIG. 2, the semiconductor layer 2 has a layered structure including an n-type (first conductivity type) semiconductor substrate 6 and an n-type epitaxial layer 7 in the preferred embodiment. The semiconductor substrate 6 and the epitaxial layer 7 may be an SiC semiconductor substrate and an SiC epitaxial layer, respectively. The semiconductor substrate 6 forms the second principal surface 4 of the semiconductor layer 2, and the epitaxial layer 7 forms the first principal surface 3 of the semiconductor layer 2.

The first principal surface 3 of the semiconductor layer 2 may be a front surface 7a on the side opposite to the semiconductor substrate 6 in the epitaxial layer 7, and the second principal surface 4 of the semiconductor layer 2 may be a front surface 6a on the side opposite to the epitaxial layer 7 in the semiconductor substrate 6. For example, N (nitrogen), P (phosphorus), As (arsenic), or the like may be used as an n-type impurity contained in the semiconductor substrate 6 and the epitaxial layer 7.

The Schottky barrier diode 1 includes a cathode electrode 8 formed at the second principal surface 4 of the semiconductor layer 2 (front surface 6a of the semiconductor substrate 6). The cathode electrode 8 is an ohmic electrode with which the whole area of the second principal surface 4 of the semiconductor layer 2 (front surface 6a of the semiconductor substrate 6) is covered. The cathode electrode 8 includes a metal that makes ohmic contact with n-type SiC. For example, Ti/Ni/Ag, Ti/Ni/Au/Ag, or the like can be described as such a metal.

The thickness TS of the semiconductor substrate 6 may be, for example, not less than 40 μm and not more than 150 μm. The thickness TS may be, for example, not less than 40 μm and not more than 50 μm, not less than 50 μm and not more than 60 μm, not less than 60 μm and not more than 70 μm, not less than 70 μm and not more than 80 μm, not less than 80 μm and not more than 90 μm, not less than 90 μm and not more than 100 μm, not less than 100 μm and not more than 110 μm, not less than 110 μm and not more than 120 μm, not less than 120 μm and not more than 130 μm, not less than 130 μm and not more than 140 μm, or not less than 140 μm and not more than 150 μm. Preferably, the thickness TS is not less than 40 μm and not more than 130 μm. The thickness TE of the epitaxial layer 7 may be, for example, not less than 1 μm and not more than 50 μm. The thickness TE may be, for example, not less than 1 μm and not more than 5 μm, not less than 5 μm and not more than 10 μm, not less than 10 μm and not more than 15 μm, not less than 15 μm and not more than 20 μm, not less than 20 μm and not more than 25 μm, not less than 25 μm and not more than 30 μm, not less than 30 μm and not more than 35 μm, not less than 35 μm and not more than 40 μm, not less than 40 μm and not more than 45 μm, or not less than 45 μm and not more than 50 μm. Preferably, the thickness TE is not less than 5 μm and not more than 15 μm.

The n-type impurity concentration of the epitaxial layer 7 may be equal to or less than the n-type impurity concentration of the semiconductor substrate 6, and, preferably, is less than the n-type impurity concentration of the semiconductor substrate 6. The n-type impurity concentration of the semiconductor substrate 6 may be, for example, not less than 1.0×10¹⁸ cm⁻³ and not more than 1.0×10²¹ cm⁻³. The n-type impurity concentration of the epitaxial layer 7 may be, for example, not less than 1.0×10¹⁵ cm⁻³ and not more than 1.0×10¹⁸ cm⁻³.

An active region 9 and a non-active region 10 are set at the first principal surface 3 of the semiconductor layer 2 (front surface 7a of the epitaxial layer 7). The active region 9 is set at a central portion of the first principal surface 3 of the semiconductor layer 2 at a distance inwardly from the side surfaces 5a to 5d of the semiconductor layer 2 in a plan view. The active region 9 is set in a quadrangular shape having four sides parallel to the side surfaces 5a to 5d of the semiconductor layer 2 in a plan view.

The non-active region 10 is set between the side surfaces 5a to 5d of the semiconductor layer 2 and the active region 9. The non-active region 10 is set in an endless shape (in the preferred embodiment, quadrangular annular shape) surrounding the active region 9 in a plan view.

The Schottky barrier diode 1 additionally includes a p-type (second conductivity type) guard region 30 formed at a surface layer portion of the first principal surface 3 of the semiconductor layer 2 (surface layer portion of the front surface 7a of the epitaxial layer 7) in the non-active region 10.

Referring to FIG. 3, the guard region 30 is formed in an endless shape (for example, quadrangular annular shape, or quadrangular annular shape whose corner has been chamfered, or circular annular shape) surrounding the active region 9 in a plan view. Thereby, the guard region 30 is formed as a guard ring region. In the preferred embodiment, the active region 9 may be a region defined by the guard region 30.

The guard region 30 includes a first guard region 31 and a plurality of (in the example of FIG. 3, five) second guard regions 32 that surround the first guard region 31 and that have a width narrower than the first guard region 31. The plurality of second guard regions 32 are provided at equal intervals therebetween. Unlike the example of FIG. 3, the guard region 30 may be formed by a single endless region (for example, region of quadrangular annular shape, or quadrangular annular shape whose corner has been chamfered, or circular annular shape).

Referring to FIG. 2, the Schottky barrier diode 1 includes an annular field insulation film 13 formed on the first principal surface 3 of the semiconductor layer 2. The field insulation film 13 as an example of an insulation layer covers a part of the first principal surface 3 of the semiconductor layer 2 in the non-active region 10. The field insulation film 13 has an opening 12 that exposes a part of the first principal surface 3 of the semiconductor layer 2.

The size of the active region 9 may be, for example, not less than 0.1 mm² and not more than 400 mm². The field insulation film 13 may have a single-layer structure consisting of, for example, a silicon oxide (SiO₂) layer or a silicon nitride (SiN) layer. The thickness of the field insulation film 13 may be, for example, not less than 0.5 μm and not more than 3 μm.

The field insulation film 13 has a first surface 13a contiguous to the first principal surface 3, a second surface 13b on the side opposite to the first surface 13a, and an inner surface 13c and an outer surface 13d that connect the first surface 13a and the second surface 13b together. The inner surface 13c is an inclined surface that is inclined in the field insulation film 13 so as to make an acute angle between the inner surface 13c and the first principal surface 3. The outer surface 13d is an inclined surface that is inclined in the field insulation film 13s so as to make an acute angle between the outer surface 13d and the first principal surface 3.

The Schottky barrier diode 1 additionally includes a Schottky electrode 15 and an anode electrode 14 as an example of a front surface electrode formed on the Schottky electrode 15.

The Schottky electrode 15 is formed on the first principal surface 3 of the semiconductor layer 2, and makes a Schottky junction SJ between the Schottky electrode 15 and the semiconductor layer 2 (epitaxial layer 7). The Schottky junction SJ is formed in the vicinity of a contact interface between a first portion 151 and the epitaxial layer 7. The thickness of the Schottky electrode 15 may be, for example, not less than 50 nm and not more than 500 nm.

The Schottky electrode 15 includes a first covering portion 18 that covers the first principal surface 3 of the semiconductor layer 2 in the active region 9 and a second covering portion 19 that covers the field insulation film 13. The second covering portion 19 covers the entirety of the inner surface 13c of the field insulation film 13 and a part of the second surface 13b. Therefore, the field insulation film 13 is disposed between the first principal surface 3 of the semiconductor layer 2 and the Schottky electrode 15.

Referring to FIG. 4 and FIG. 5, the Schottky electrode 15 includes a first portion 151 contiguous to the first principal surface 3 of the semiconductor layer 2 and a second portion 152 formed on the first portion 151. A boundary portion 153 shown by a broken line in FIG. 4 and FIG. 5 may be formed between the first portion 151 and the second portion 152. The first portion 151 and the second portion 152 may be referred to as a first layer 151 and a second layer 152, respectively, if it is possible to ascertain that these first and second portions are formed in a layered manner by means of an electron microscope, such as SEM or TEM. Additionally, the first portion 151 and the second portion 152 may be referred to as a lower layer 151 and an upper layer 152, respectively, because these first and second portions have an upper-lower positional relationship in FIG. 4 and FIG. 5. Additionally, the first portion 151 and the second portion 152 may be referred to as a first metal portion 151 (first metal layer 151) and a second metal portion 152 (second metal layer 152), respectively, because the first portion 151 and the second portion 152 are each made of a metal. A third portion including a material differing from that of the first portion 151 and that of the second portion 152 may be interposed as an intermediate portion (intermediate layer) between the first portion 151 and the second portion 152 (not shown).

The boundary portion 153 between the first portion 151 and the second portion 152 is formed over the entirety of the Schottky electrode 15 in a lateral direction along the first principal surface 3 of the semiconductor layer 2. Thereby, the Schottky electrode 15 is divided into the first portion 151 and the second portion 152 in the up-down direction so that the boundary portion 153 is exposed to its end surface 154 as shown in FIG. 5. Therefore, a layered structure including the first portion 151 and the second portion 152 is formed in the first covering portion 18 of the Schottky electrode 15, and a layered structure including the first portion 151 and the second portion 152 is likewise formed in the second covering portion 19.

The thickness of the first portion 151 may be smaller than the thickness of the second portion 152. For example, the thickness of the first portion 151 may be, for example, not less than 5 nm and not more than 300 nm, and the thickness of the second portion 152 may be, for example, not less than 50 nm and not more than 500 nm. Additionally, the thickness of the first portion 151 may be less than half of the total thickness of the Schottky electrode 15. On the other hand, the thickness of the second portion 152 may be equal to or more than half of the total thickness of the Schottky electrode 15.

The first portion 151 is a part of the Schottky electrode 15 that makes a Schottky junction SJ between the first portion 151 and the semiconductor layer 2 (epitaxial layer 7), and is a part, which is made of Ti, of the Schottky electrode 15. Herein, the term “part made of Ti” may denote a part, which includes only Ti as a principal component, of the Schottky electrode 15. For example, the first portion 151 may be a part in which Ti exceeding 50.0 atm % in amount is detected when an element-content analysis is made in a direction from the Schottky electrode 15 toward the semiconductor layer 2 (in the preferred embodiment, third direction Z) according to a predetermined quantitative-analysis method (for example, energy dispersive X-ray spectroscopy (EDX), X-ray photoelectron spectroscopy (XPS), or Auger electron spectroscopy (AES)).

The second portion 152 is a part, which is in non-contact with the semiconductor layer 2 (epitaxial layer 7) at least through the first portion 151, and is a part, which is made of Ti and N. Herein, the term “part made of Ti and N” may denote a part, which includes both Ti and N as principal components, of the Schottky electrode 15. For example, the second portion 152 may be a part in which Ti exceeding 30.0 atm % in amount and N exceeding 30.0 atm % in amount are detected when an element-content analysis is made in a direction from the Schottky electrode 15 toward the semiconductor layer 2 (in the preferred embodiment, third direction Z) according to a predetermined quantitative-analysis method (the same as above).

The first guard region 31 is contiguous to the Schottky electrode 15 and to the field insulation film 13, and the plurality of second guard regions 32 are contiguous to the field insulation film 13 (see FIG. 5).

The anode electrode 14 is formed to cover the entirety of the front surface of the Schottky electrode 15. Therefore, the anode electrode 14 straddles between the first covering portion 18 and the second covering portion 19 of the Schottky electrode 15. The anode electrode 14 is made of, for example, an Al alloy or Al. The Al alloy may include at least one among, for example, an AlCu alloy, an AlSi alloy, and an AlSiCu alloy. Herein, “Al alloy or Al” may be a metal in which Al exceeding 70.0 atm % in amount is detected when an element-content analysis is made in a direction from the anode electrode 14 toward the semiconductor layer 2 (in the preferred embodiment, third direction Z), for example, according to a predetermined quantitative-analysis method (for example, energy dispersive X-ray spectroscopy (EDX), X-ray photoelectron spectroscopy (XPS), or Auger electron spectroscopy (AES)). Referring to FIG. 2 and FIG. 4, the anode electrode 14 includes a connection portion 16 having a front surface 16a to which a connection member 22, such as a bonding wire, is connected.

The Schottky barrier diode 1 additionally includes a passivation layer 20 as an example of a second insulation layer formed on the connection portion 16 of the anode electrode 14. The passivation layer 20 may have a single-layer structure consisting of a silicon oxide layer or a silicon nitride layer, or may have a layered structure consisting of a silicon oxide layer and a silicon nitride layer. If the passivation layer 20 has the layered structure, the silicon oxide layer may be formed on the silicon nitride layer, or the silicon nitride layer may be formed on the silicon oxide layer. In the preferred embodiment, the passivation layer 20 has a single-layer structure consisting of a silicon nitride layer.

The passivation layer 20 is formed at a distance inwardly from the side surfaces 5a to 5d of the semiconductor layer 2 in a plan view. A pad opening 21 that exposes a part of the front surface 16a of the connection portion 16 of the anode electrode 14 as a connection region 23 with the connection member 22 is formed in the passivation layer 20.

The Schottky barrier diode 1 additionally includes a p-type (second conductivity type) impurity region 40 formed at the surface layer portion of the first principal surface 3 of the semiconductor layer 2 (front surface 7a of the epitaxial layer 7) in the active region 9 so as to be contiguous to the Schottky electrode 15. The impurity region 40 makes a p-n junction PJ between the impurity region 40 and the epitaxial layer 7 of the semiconductor layer 2. The p-n junction PJ is formed in the vicinity of a contact interface between the impurity region 40 and the epitaxial layer 7.

Referring to FIG. 3, the impurity region 40 includes a plurality of linear impurity regions 41 disposed in a stripe manner. The p-type impurity concentration of the impurity region 40 may be, for example, not less than 10×10¹⁶ cm⁻³ and not more than 10×10²¹ cm⁻³.

The plurality of linear impurity regions 41 are disposed at equal intervals in the second direction Y, and each of the linear impurity regions 41 extends in the first direction X. The plurality of linear impurity regions 41 are integrated with the first guard region 31. In detail, both end portions of the linear impurity region 41 in the first direction X are connected to an inward end portion of the first guard region 31.

Referring to FIG. 4, a bottom portion of each of the linear impurity regions 41 (bottom portion 40a of the impurity region 40) is contiguous to the epitaxial layer 7. The bottom portion of each of the linear impurity regions 41 may include a pair of curved portions toward the second principal surface 4 of the semiconductor layer 2 and a flat portion that connects the pair of curved portions together.

The width W of the linear impurity region 41 in the second direction Y may be, for example, not less than 0.5 μm and not more than 10 μm. The depth D of the linear impurity region 41 may be, for example, not less than 0.3 μm and not more than 1.5 μm. The pitch P of the plurality of linear impurity regions 41 in the second direction Y may be, for example, not less than 1.0 μm and not more than 5 μm.

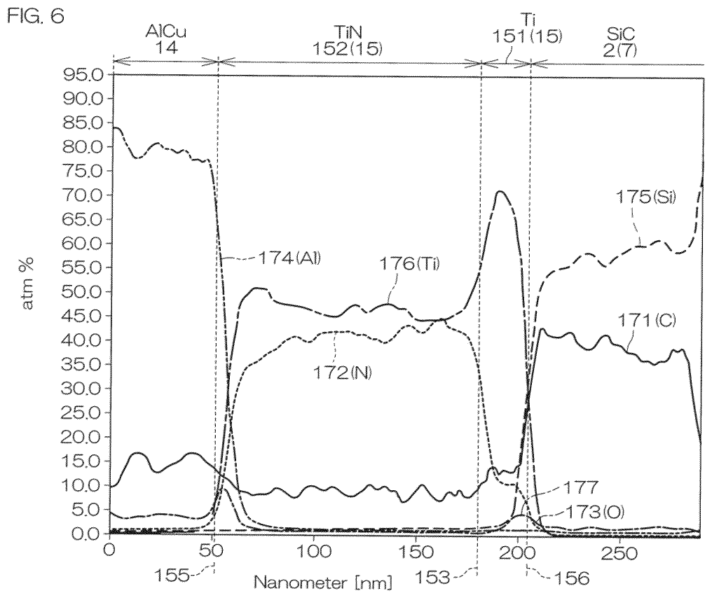

Next, constituent elements of both the Schottky electrode 15 and the anode electrode 14 will be described in more detail with reference to FIG. 6.

FIG. 6 is a view showing an analysis result of the constituent elements of the Schottky electrode 15 and the anode electrode 14. More specifically, FIG. 6 shows an analysis result obtained by measuring the constituent elements of the Schottky electrode 15 and the anode electrode 14 at a position of the first covering portion 18 of the Schottky electrode 15 in the first and second directions X and Y according to the energy dispersive X-ray spectroscopy. In the preferred embodiment, elements of carbon (C), nitrogen (N), oxygen (O), aluminum (Al), silicon (Si), and titanium (Ti) are detected. The acceleration voltage condition of the energy dispersive X-ray spectroscopy when these elements are detected may be, for example, 150 kV to 250 kV.

In FIG. 6, the horizontal axis represents a depth in a direction from the front surface 16a toward the semiconductor layer 2 of the anode electrode 14, and the position of the front surface 16a is 0 (zero) in depth. A plurality of broken lines crossing the horizontal axis represent a boundary portion 155 between the anode electrode 14 and the Schottky electrode 15 (second portion 152), a boundary portion 153 between the second portion 152 of the Schottky electrode 15 and the first portion 151, and a boundary portion 156 between the Schottky electrode 15 (first portion 151) and the semiconductor layer 2 (epitaxial layer 7), respectively. The vertical axis of FIG. 6 represents the concentration (atm %) of each constituent element.

In FIG. 6, concentration profiles 171 to 176 of carbon (C), nitrogen (N), oxygen (O), aluminum (Al), silicon (Si), and titanium (Ti) are individually shown as constituent elements that have been detected. The concentration profile 171 to 176 of each element straddles each of the boundary portions 155, 153, and 156, and is continuous. A part, which is in an area between 0 of the horizontal axis and the boundary portion 155, of the concentration profile 171 to 176 of each element shows the atomic fraction of the constituent element of the anode electrode 14. Additionally, a part, which is in an area between the boundary portion 155 and the boundary portion 153, of the concentration profile 171 to 176 of each element and a part, which is in an area between the boundary portion 153 and the boundary portion 156, of the concentration profile 171 to 176 of each element show the atomic fraction of the constituent element of the second portion 152 of the Schottky electrode 15 and the atomic fraction of the constituent element of the first portion 151 of the Schottky electrode 15, respectively.

Referring to FIG. 6, first, the anode electrode 14 (AlCu) contains aluminum (Al) as a principal component at a concentration of not less than 75.0 atm % and not more than 85.0 atm %. Additionally, the anode electrode 14 contains carbon (C) as an accessory component at a concentration of not less than 10.0 atm % and not more than 20.0 atm % and oxygen (O) as an accessory component at a concentration of not less than 2.0 atm % and not more than 5.0 atm %. Additionally, the anode electrode 14 does not substantially contain nitrogen (N), silicon (Si), and titanium (Ti) because nitrogen (N), silicon (Si), and titanium (Ti) are hardly detected in the anode electrode 14. Herein, the term “not substantially contain” denotes a case in which the concentration may be less than at least 2.0 atm % in the measurement method (energy dispersive X-ray spectroscopy) of FIG. 6. Conversely speaking, the term “substantially contains” denotes a case in which the concentration may be equal to or more than at least 2.0 atm %.

Next, the second portion 152 (TiN) of the Schottky electrode 15 contains titanium (Ti) as a principal component at a concentration of not less than 40.0 atm % and not more than 50.0 atm % and nitrogen (N) as a principal component at a concentration of not less than 35.0 atm % and not more than 45.0 atm %. Additionally, the second portion 152 of the Schottky electrode 15 contains carbon (C) as an accessory component at a concentration of not less than 5.0 atm % and not more than 15.0 atm %. Additionally, the second portion 152 of the Schottky electrode 15 does not substantially contain oxygen (O), aluminum (Al), and silicon (Si) because oxygen (O), aluminum (Al), and silicon (Si) are hardly detected in the Schottky electrode 15. In FIG. 6, oxygen (O) is an element not substantially contained, and yet thickens in the vicinity of the boundary portion 155. Presumably, the reason is that the front surface of the Schottky electrode 15 comes into contact with air, and is oxidized when a semiconductor wafer 75 (described later) is transported to a forming device 84 of an anode-electrode 14 (for example, sputtering device) after the Schottky electrode 15 is formed.

Next, the first portion 151 (oxygen-containing Ti) of the Schottky electrode 15 contains titanium (Ti) as a principal component at a concentration of not less than 50.0 atm % and not more than 70.0 atm %. Additionally, the first portion 151 of the Schottky electrode 15 contains carbon (C) as an accessory component at a concentration of not less than 5.0 atm % and not more than 15.0 atm %, nitrogen (N) as an accessory component at a concentration of not less than 5.0 atm % and not more than 15.0 atm %, and oxygen (O) as an accessory component at a concentration of not less than 2.0 atm % and not more than 10.0 atm %. Additionally, the first portion 151 of the Schottky electrode 15 does not substantially contain aluminum (Al) and silicon (Si) because aluminum (Al) and silicon (Si) are hardly detected in the Schottky electrode 15.

Herein, oxygen (O) contained in the first portion 151 of the Schottky electrode 15 selectively thickens in the vicinity of the boundary portion 156. In other words, oxygen (O) contained therein is in a more thickened state on the side closer to the boundary portion 156 than to a central portion in the depth direction (rightward direction of the horizontal axis) of the first portion 151 of FIG. 6. More specifically, in the first portion 151, the concentration profile 173 of oxygen (O) has a peak 177 on the side closer to the boundary portion 156 than to the central portion in the depth direction of the first portion 151.

Next, the semiconductor layer 2 (SiC) contains silicon (Si) as a principal component at a concentration of not less than 50.0 atm % and not more than 60.0 atm % and carbon (C) as a principal component at a concentration of not less than 35.0 atm % and not more than 45.0 atm %. Additionally, the semiconductor layer 2 does not substantially contain nitrogen (N), oxygen (O), aluminum (Al), and titanium (Ti) because nitrogen (N), oxygen (O), aluminum (Al), and titanium (Ti) are hardly detected in the semiconductor layer 2.

As described above, FIG. 6 shows an analysis result of the constituent elements of both the Schottky electrode 15 and the anode electrode 14 at the position of the first covering portion 18 of the Schottky electrode 15. The analysis result at the position of the first covering portion 18 may differ from an analysis result at the position of the second covering portion 19. For example, the first portion 151 of the Schottky electrode 15 is not required to substantially contain oxygen (O) in the second covering portion 19 (part at which the first portion 151 is in contact with the field insulation film 13). In other words, in the first portion 151, oxygen (O) may be selectively contained in the first covering portion 18. Additionally, the semiconductor layer 2 may contain oxygen 83 near the first principal surface 3 immediately under the second covering portion 19 (part at which the semiconductor layer 2 is in contact with the field insulation film 13) as shown in FIG. 5. In other words, the semiconductor layer 2 may contain the oxygen 83 near the first principal surface 3 in the non-active region 10. In other words, preferably, in the semiconductor layer 2, the oxygen 83 is not contained in a part contiguous to the first portion 151 of the Schottky electrode 15. This makes it possible to restrain an increase in resistance of the active region 9 of the semiconductor layer 2, thereby making it possible to efficiently pass a forward current.

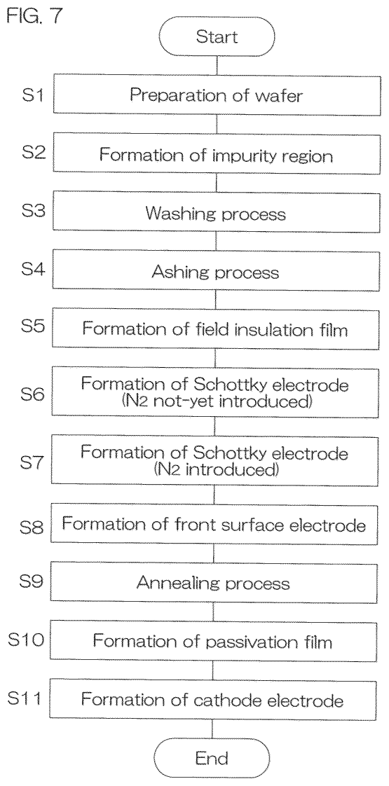

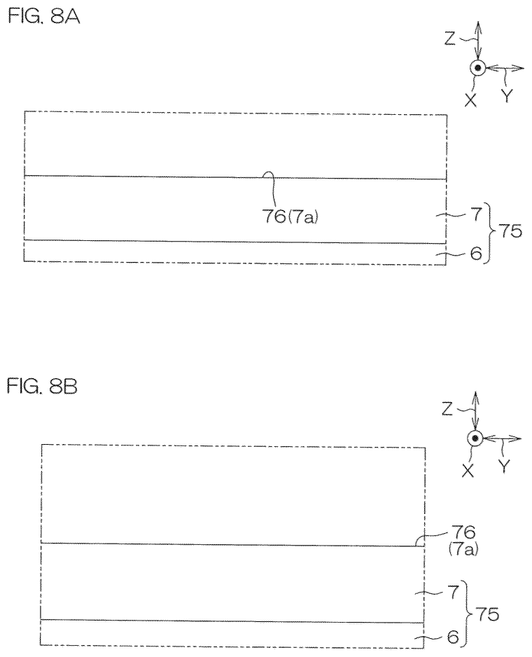

FIG. 7 is a flowchart of a manufacturing process of the Schottky barrier diode 1. FIGS. 8A and 8B to FIGS. 15A and 15B are views showing a part of the manufacturing process of the Schottky barrier diode 1 in order of process steps. In FIGS. 8A and 8B to FIGS. 15A and 15B, drawings having drawing numbers to each of which “A” is added are cross-sectional views corresponding to FIG. 4, and drawings having drawing numbers to each of which “B” is added are cross-sectional views corresponding to FIG. 5.

First, a semiconductor wafer 75 is prepared (Step S1) with reference to FIG. 8A and FIG. 8B. The semiconductor wafer 75 serves as a base of the semiconductor layer 2. The semiconductor wafer 75 has a first wafer principal surface 76 on one side and a second wafer principal surface on the other side. The first wafer principal surface 76 and the second wafer principal surface correspond to the first principal surface 3 and the second principal surface 4 of the semiconductor layer 2, respectively.

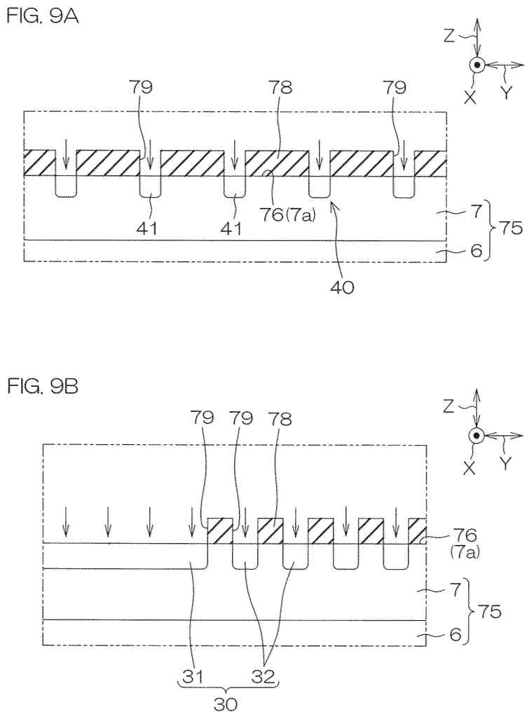

Thereafter, referring to FIG. 9A and FIG. 9B, a mask 78 is formed at the first wafer principal surface 76 of the semiconductor wafer 75. The mask 78 may be a hard mask, such as a silicon oxide mask, or a photoresist. The mask 78 has an opening 79 in a region in which the guard region 30 and the impurity region 40 are to be formed. Thereafter, a p-type impurity is injected into the first wafer principal surface 76 of the semiconductor wafer 75 through the mask 78. Thereby, the guard region 30 and the impurity region 40 are formed (Step S2). Thereafter, the mask 78 is removed.

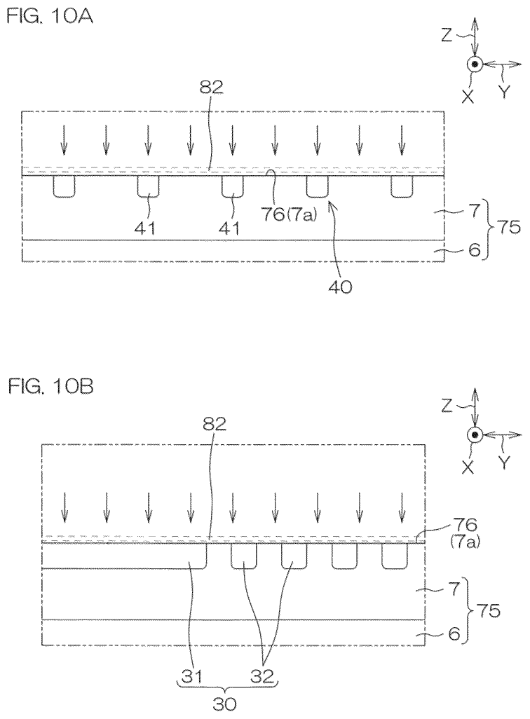

Thereafter, referring to FIG. 10A and FIG. 10B, a washing step of washing the first wafer principal surface 76 of the semiconductor wafer 75 is performed (Step S3). In this step, for example, residues (particles) that remain after removing the mask 78 described above or resist residues or the like that have been used for dry etching, which has been performed as needed, are removed by means of a chemical liquid 82. In the preferred embodiment, hydrofluoric-acid-based (HF) washing liquid is used as the chemical liquid 82.

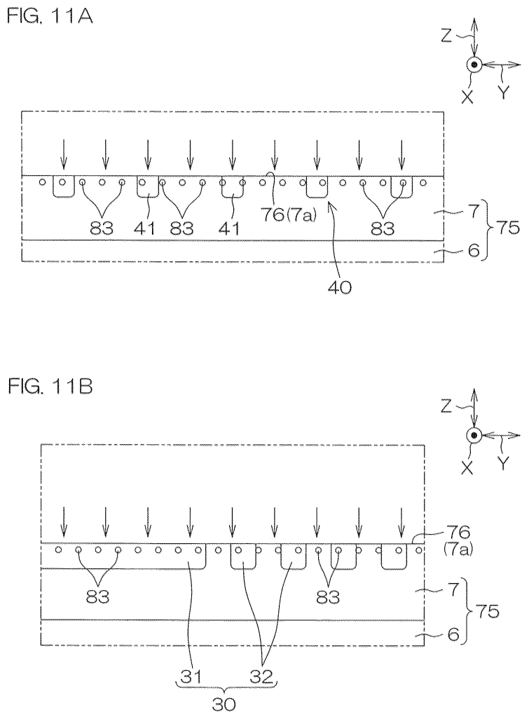

Thereafter, referring to FIG. 11A and FIG. 11B, the oxygen 83 is introduced into the first wafer principal surface 76 of the semiconductor wafer 75 (Step S4). In the preferred embodiment, the oxygen 83 is introduced into the entirety of the first wafer principal surface 76 including both the guard region 30 and the impurity region 40 through an oxygen-plasma ashing process. In other words, the oxygen 83 is introduced not only into the epitaxial layer 7 but also into both the guard region 30 and the impurity region 40.

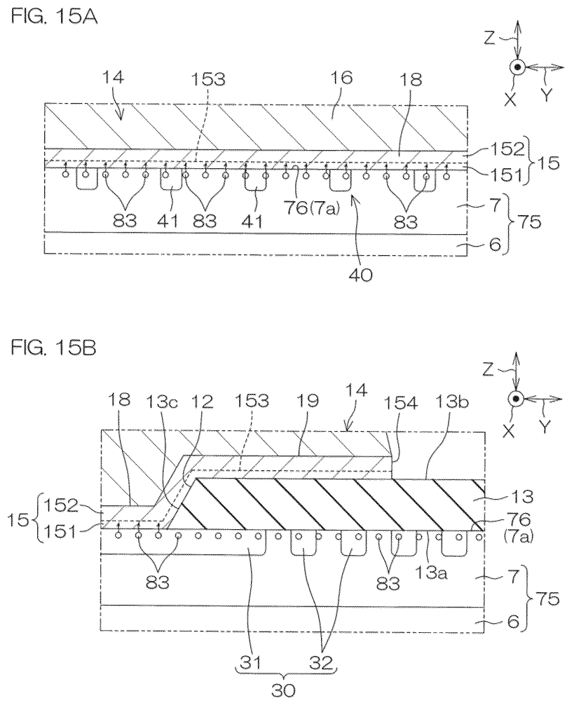

Preferably, the oxygen 83 is selectively introduced into a surface layer portion of the first wafer principal surface 76 of the semiconductor wafer 75. This makes it possible to prevent the oxygen 83 from remaining in the active region 9 after annealing treatment described later (see FIGS. 15A and 15B) is completed. For example, as oxygen-plasma ashing conditions, the pressure in a chamber may be not less than 10 Pa and not more than 1000 Pa, the output may be not less than 0.1 kW and not more than 5 kW, and the oxygen gas flow rate may be not less than 100 sccm and not more than 1000 sccm.

As thus described, an oxygen-plasma irradiating step is performed after the washing step of washing the first principal surface 3 of the semiconductor layer 2 (see FIGS. 10A and 10B). Therefore, it is possible to prevent the oxygen 83 that has been introduced into the semiconductor layer 2 by means of irradiation from being removed in the washing step.

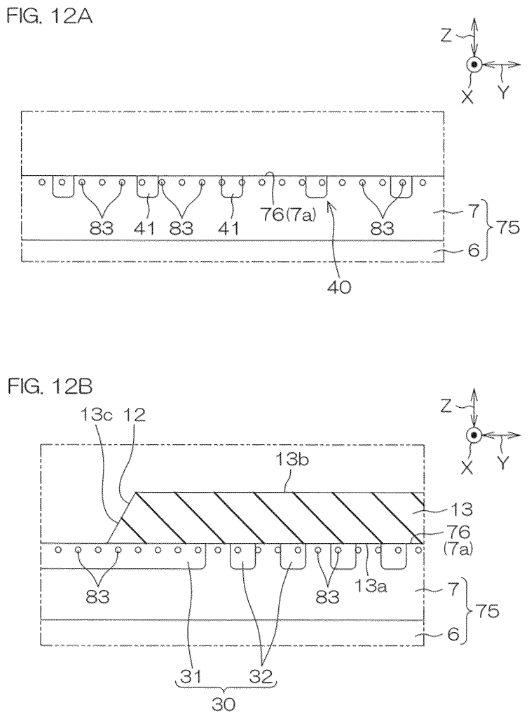

Thereafter, referring to FIG. 12A and FIG. 12B, the field insulation film 13 is formed at the first wafer principal surface 76 of the semiconductor wafer 75 (Step S5). The field insulation film 13 may be formed by, for example, a CVD (Chemical Vapor Deposition) method.

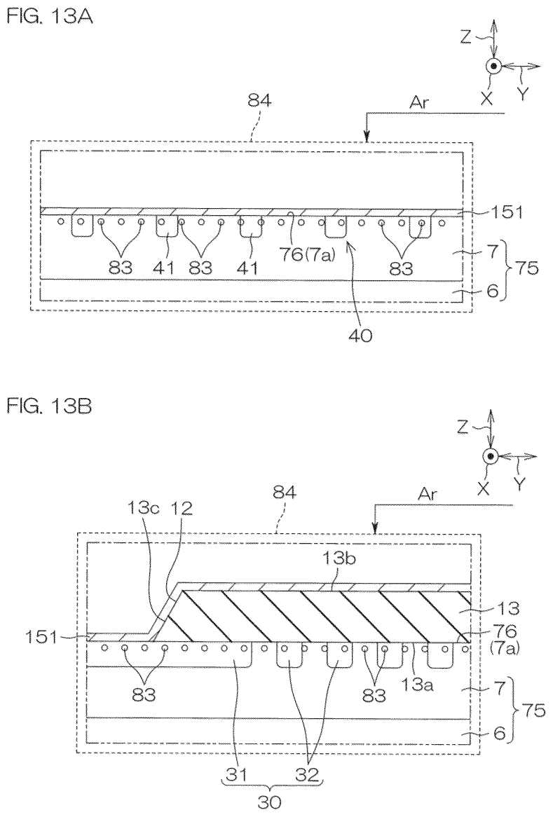

Thereafter, referring to FIG. 13A and FIG. 13B, the first portion 151 of the Schottky electrode 15 is formed at the first wafer principal surface 76 of the semiconductor wafer 75 (Step S6). For example, the semiconductor wafer 75 is carried into a device 84 that forms an electrode. The device 84 may be an evaporation deposition device although the device 84 is a sputtering device in the preferred embodiment. Thereafter, an argon (Ar) gas is introduced into a chamber of the device 84, and sputtering in which Ti is used as a target is performed in a state in which a nitrogen (N₂) gas is not introduced. Thereby, the first portion 151 in which Ti is a principal component is deposited on the semiconductor wafer 75.

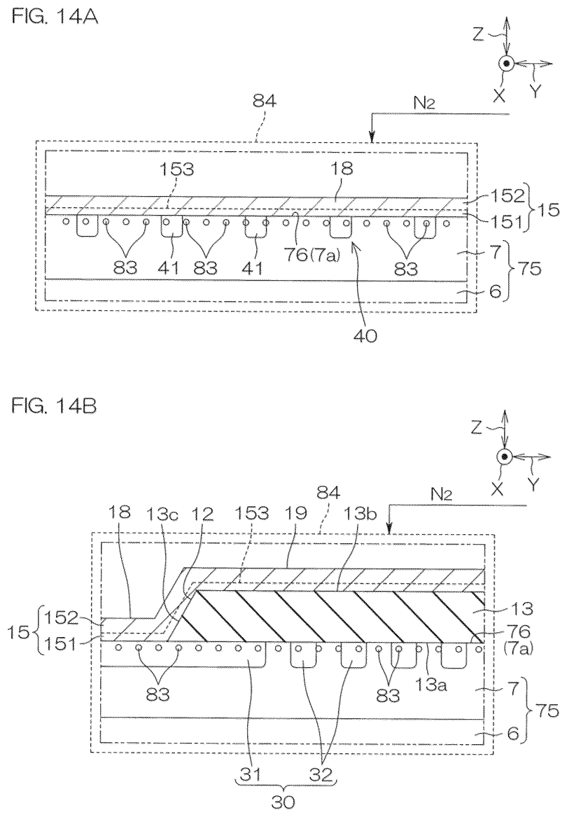

Thereafter, referring to FIG. 14A and FIG. 14B, the second portion 152 is formed on the first portion 151 of the Schottky electrode 15 (Step S7). More specifically, subsequently to deposition of the first portion 151 (without carrying the semiconductor wafer 75 out of the device 84), Ti is additionally deposited on the first wafer principal surface 76 of the semiconductor wafer 75 while introducing a nitrogen (N₂) gas into the chamber of the device 84. Thereby, the second portion 152 in which Ti and N are principal components is deposited on the semiconductor wafer 75, and the Schottky electrode 15 including the first portion 151 and the second portion 152 is formed.

Thereafter, referring to FIG. 15A and FIG. 15B, the anode electrode 14 is formed on the Schottky electrode 15 (Step S8). For example, the semiconductor wafer 75 may be temporarily carried out of the device 84, and the target in the chamber of the device 84 may be changed to Al and Cu, and then the sputtering method may be again performed by the device 84. Thereby, the anode electrode 14 in which Al and Cu are principal components is deposited. There is a case in which the front surface of the second portion 152 of the Schottky electrode 15 is oxidized in the air when the semiconductor wafer is temporarily carried out.

Thereafter, needless parts of both the anode electrode 14 and the Schottky electrode 15 are removed by patterning. Thereafter, annealing treatment is performed (Step S9). As a result of this annealing treatment, the oxygen 83 introduced into the surface layer portion of the first wafer principal surface 76 of the semiconductor wafer 75 diffuses into the first portion 151 of the Schottky electrode 15, and the oxygen 83 is contained in the first portion 151. At this time, the oxygen 83 introduced into the first wafer principal surface 76 contiguous to the field insulation film 13 may stay in the semiconductor wafer 75 after the annealing treatment is performed.

Thereafter, the passivation layer 20 is formed on the anode electrode 14 (Step S10) by, for example, the CVD method. Thereafter, the cathode electrode 8 is formed at a second wafer principal surface 77 of the semiconductor wafer 75 by, for example, the sputtering method (Step S11). Thereafter, the semiconductor wafer 75 is cut, and a plurality of Schottky barrier diodes 1 are cut out. The Schottky barrier diode 1 described above is obtained through the process including the above-described steps.

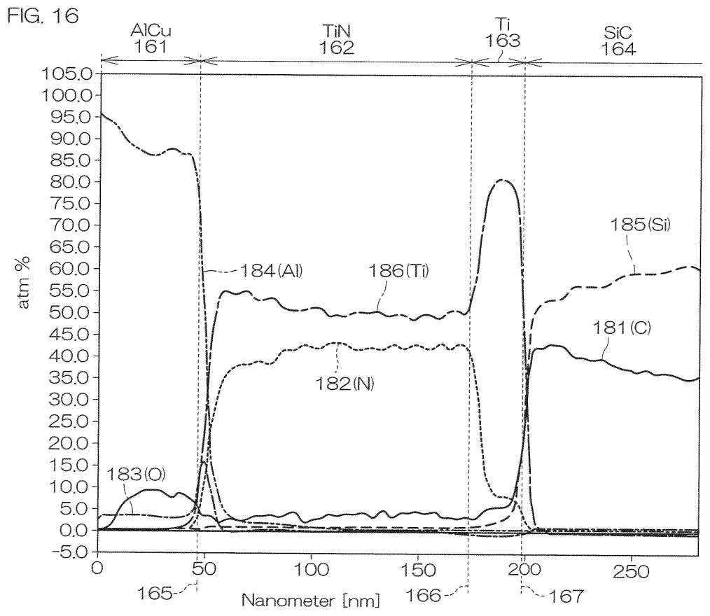

As described above, with the Schottky barrier diode 1, the Schottky electrode 15 has the first portion 151 selectively formed near the first principal surface 3 of the semiconductor layer 2 in the thickness direction of the Schottky electrode 15. This first portion 151 is made of Ti that contains oxygen (O). This makes it possible to reduce the forward voltage of the Schottky electrode 15. This effect can be described with reference to, for example, FIG. 6, and FIG. 16 to FIGS. 18A, 18B.

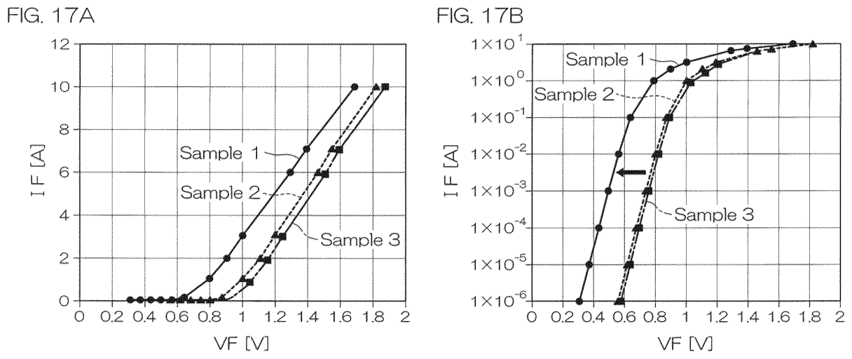

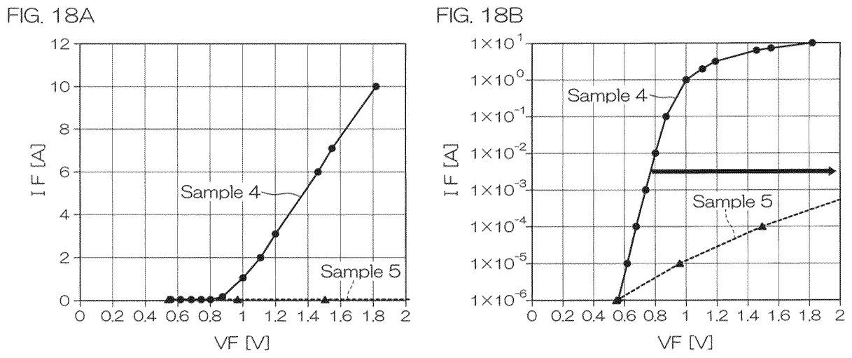

FIG. 16 is a view showing an analysis result of constituent elements of both a Schottky electrode and an anode electrode of the Schottky barrier diode according to sample 2. FIG. 17A and FIG. 17B show I-V curves of the Schottky barrier diode according to samples 1 to 3. FIG. 18A and FIG. 18B show I-V curves of the Schottky barrier diode according to samples 4 and 5.

Herein, the reduction effect of the forward voltage of the Schottky barrier diode 1 of the present disclosure will be described by comparing forward voltages of five samples 1 to 5 with each other.

Sample 1 is the above-described Schottky barrier diode 1 manufactured according to the flow of FIG. 7. Therefore, constituent elements of both the Schottky electrode 15 and the anode electrode 14 of sample 1 are as shown in FIG. 6.

Sample 2 is a Schottky barrier diode manufactured without performing the “ashing process” of Step S4 in the flow of FIG. 7. When the anode electrode, the second portion of the Schottky electrode, the first portion of the Schottky electrode, and the semiconductor layer of sample 2 are designated as an anode electrode 161, a second portion 162 of the Schottky electrode, a first portion 163 of the Schottky electrode, and a semiconductor layer 164, respectively, constituent elements of these are as shown in FIG. 16. Reference numerals 165, 166, 167 represent a boundary portion 165 between the anode electrode 161 and the second portion 162 of the Schottky electrode, a boundary portion 166 between the second portion 162 of the Schottky electrode and the first portion 163, and a boundary portion 167 between the Schottky electrode (first portion 163) and the semiconductor layer 164, respectively, in FIG. 16. Concentration profiles 181 to 186 of FIG. 16 are concentration profiles of carbon (C), nitrogen (N), oxygen (O), aluminum (Al), silicon (Si), and titanium (Ti), respectively.

Referring to FIG. 6 and FIG. 16, the Schottky barrier diode of sample 2 differs from the Schottky barrier diode 1 of sample 1 mainly in that the first portion 163 of the Schottky electrode of sample 2 does not substantially contain oxygen (O). In other words, in FIG. 6, the concentration profile 173 of oxygen (O) contains oxygen (O) at a concentration of not less than 2.0 atm % and not more than 10.0 atm % near the boundary portion 156, whereas oxygen (O) is hardly detected near the boundary portion 167 in the concentration profile 183 of oxygen (O) of FIG. 16.

Next, sample 3 is a Schottky barrier diode manufactured by reversing the order of the “washing process” of Step S3 and the “ashing process” of Step S4 in the flow of FIG. 7. In other words, in the manufacturing process of sample 3, the oxygen 83 is introduced into the first wafer principal surface 76 of the semiconductor wafer 75, and then the chemical liquid 82 is supplied to the first wafer principal surface 76, and the washing process is performed.

Sample 4 is a Schottky barrier diode in which the Schottky electrode (whose principal component is Ti) of the Schottky barrier diode of sample 2 is replaced with a Schottky electrode whose principal component is molybdenum (Mo). In other words, in the manufacturing process of sample 4, the “ashing process” of Step S4 is not performed in the flow of FIG. 7, and, thereafter the Schottky electrode is formed by sputtering in which molybdenum (Mo) is used as a target.

Sample 5 is a Schottky barrier diode in which the Schottky electrode (whose principal component is Ti) of the Schottky barrier diode 1 of sample 1 is replaced with a Schottky electrode whose principal component is molybdenum (Mo). In other words, in the manufacturing process of sample 5, the “washing process” of Step S3 and the “ashing process” of Step S4 are performed in this order in the flow of FIG. 7, and then the Schottky electrode is formed by sputtering in which molybdenum (Mo) is used as a target. In other words, sample 5 differs from sample 4 in that the washing process and the asking process are performed.

Referring to FIG. 17A, FIG. 17B, FIG. 18A, and FIG. 18B, each horizontal axis represents the magnitude of a forward voltage applied to each of the samples 1 to 5. Each vertical axis represents the magnitude of a forward current flowing to each of the samples 1 to 5. FIG. 17B and FIG. 18B show the vertical axes of graphs of FIG. 17A and FIG. 18B by logarithm scales, respectively. In FIG. 17A and FIG. 17B, the solid line represents an I-V curve of sample 1, and the broken line represents an I-V curve of sample 2, and the alternate long and short dashed line represents an I-V curve of sample 3. Additionally, in FIG. 18A and FIG. 18B, the solid line represents an I-V curve of sample 4, and the broken line represents an I-V curve of sample 5.

In comparison between forward voltages of samples 1 to 5, it is understood that the Schottky barrier diode 1 of sample 1 rises at a lower voltage than the Schottky barrier diodes of other samples 2 to 5. In other words, the first portion 151 of the Schottky electrode 15 is Ti, and this first portion 151 contains oxygen, and, as a result, it is conceivable that the forward voltage was able to be reduced.

Referring to FIGS. 17A and 17B, oxygen (O) is not contained although the first portion 163 made of Ti is provided in sample 2, and therefore it is conceivable that the forward voltage became higher than sample 1. Additionally, in sample 3, the oxygen 83 is introduced into the first wafer principal surface 76 of the semiconductor wafer 75 through the asking process, and yet the washing process was performed after the introduction of the oxygen 83, and, as a result, it is conceivable that the oxygen 83 introduced into the first wafer principal surface 76 was removed by the chemical liquid 82. As a result, it is conceivable that the oxygen 83 did not diffuse from the semiconductor wafer 75 into the first portion 151 even if the annealing treatment (Step S9 of FIG. 7) was performed.

On the other hand, referring to FIGS. 18A and 18B, in sample 5, the “washing process” of Step S3 and the “ashing process” of Step S4 are performed in this order in the flow of FIG. 7 in the same way as in sample 1. However, unlike comparison with sample 1 and with sample 2, the first portion 151 is made of molybdenum (Mo), and therefore, resultantly, the forward voltage became higher than in sample 4 in which the ashing process is not performed.

### Second Preferred Embodiment

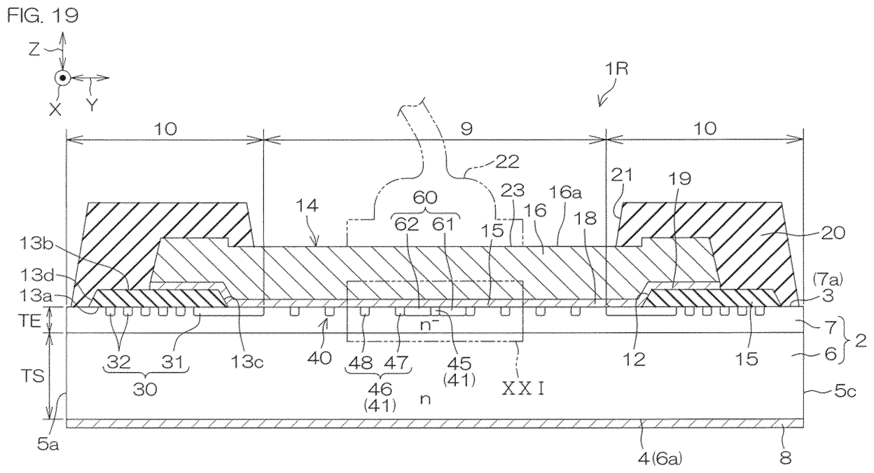

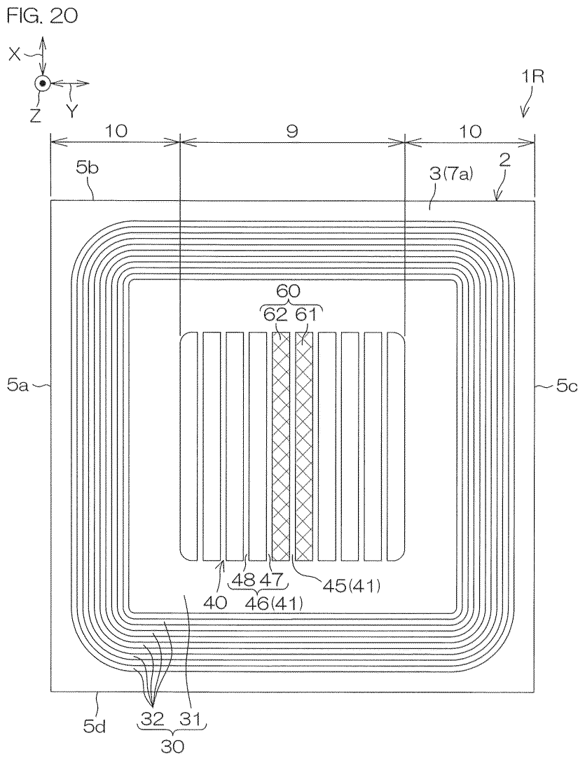

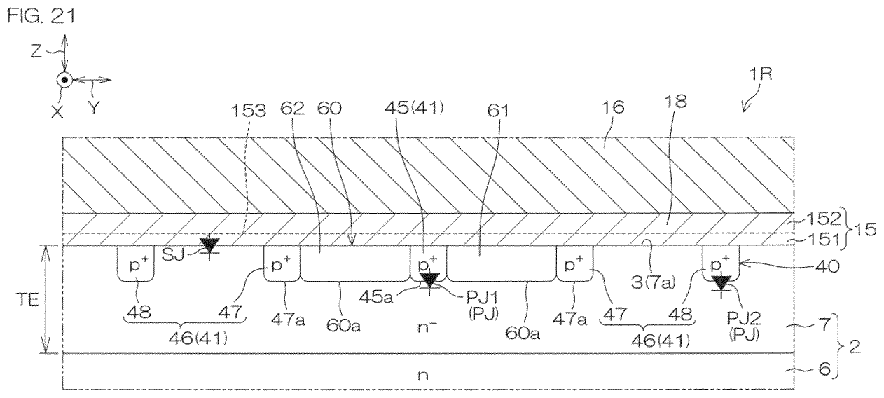

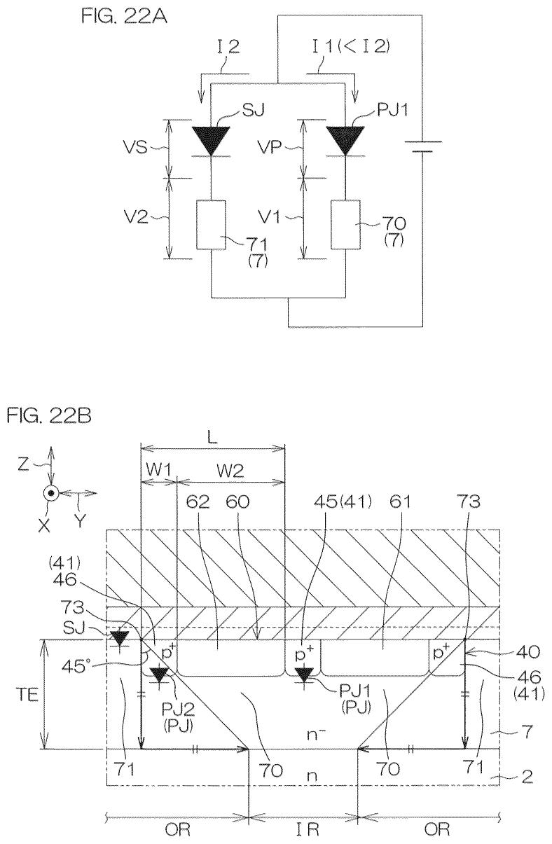

FIG. 19 is a schematic cross-sectional view of a Schottky barrier diode 1R according to a second preferred embodiment of the present disclosure. FIG. 20 is a plan view showing a state in which a structure, which is positionally higher than the first principal surface 3 of the semiconductor layer 2, of the Schottky barrier diode 1R of FIG. 19 has been removed. FIG. 21 is an enlarged view of a part surrounded by alternate long and two short dashed line XXI of FIG. 19. FIG. 22A is a circuit diagram for describing a voltage drop around an inner impurity region 45 included in the Schottky barrier diode 1R of FIG. 19. FIG. 22B is a cross-sectional view for describing a voltage drop around the inner impurity region 45.

The Schottky barrier diode 1R according to the second preferred embodiment differs from the Schottky barrier diode 1 (see FIG. 2) according to the first preferred embodiment mainly in that a lattice defect region 60 is formed at the front surface layer portion of the surface 7a of the epitaxial layer 7.

Referring to FIG. 19 to FIG. 21, the lattice defect region 60 is a region having more lattice defects than the epitaxial layer 7. The lattice defect region 60 is a region formed by injecting rare gas atoms, such as argon (Ar), into the epitaxial layer 7. Therefore, the lattice defect region 60 may be referred to as a rare-gas containing region. The impurity concentration of the lattice defect region 60 may be, for example, not less than 10×10¹⁹ cm⁻³ and not more than 10×10²¹ cm⁻³.

The lattice defect region 60 is contiguous to the Schottky electrode 15. Rare gas atoms are injected into the epitaxial layer 7, and, as a result, a crystal lattice of SiC forming the epitaxial layer 7 is broken, and a lattice defect occurs. Therefore, the lattice defect region 60 does not make a Schottky junction between the Schottky electrode 15 and the lattice defect region 60 in spite of the fact that the lattice defect region 60 is contiguous to the Schottky electrode 15, the lattice defect region 60 obstructs the flow of an electric current from the Schottky electrode 15 to the epitaxial layer 7. In other words, the lattice defect region 60 has more lattice defects than the epitaxial layer 7, and therefore the lattice defect region 60 may be a high-resistance layer that is higher in resistance than the epitaxial layer 7.

The lattice defect region 60 is provided around the single linear impurity region 41 among the plurality of linear impurity regions 41.

More specifically, the impurity region 40 includes an inner impurity region 45 disposed inside the lattice defect region 60 so as to be contiguous to the lattice defect region 60 and an outer impurity region 46 disposed outside the lattice defect region 60. The linear impurity region 41 placed inside the lattice defect region 60 among the plurality of linear impurity regions 41 functions as the inner impurity region 45, and the linear impurity region 41 placed outside the lattice defect region 60 among the plurality of linear impurity regions 41 functions as the outer impurity region 46. The inner impurity region 45 is sandwiched from both sides in the second direction Y by means of the lattice defect region 60.

The outer impurity region 46 includes a pair of outer contact impurity regions 47 disposed on the side opposite to the inner impurity region 45 with the lattice defect region 60 between the outer contact impurity regions 47 so as to be contiguous to the lattice defect region 60 and a plurality of outer noncontact impurity regions 48 disposed on the side opposite to the inner impurity region 45 with the lattice defect region 60 between the outer noncontact impurity regions 48 so as to be away from the lattice defect region 60.

The lattice defect region 60 is contiguous to the inner impurity region 45 from both sides in the second direction Y. In the example of FIG. 20, both end portions of the lattice defect region 60 in the first direction X are contiguous to an inward end in the first guard region 31. Unlike the example of FIG. 20, both end portions of the lattice defect region 60 in the first direction X are not contiguous to the inward end in the first guard region 31, and may face the first guard region 31 across the epitaxial layer 7.

The lattice defect region 60 includes a first lattice defect region 61 that linearly extends in the first direction X and that is contiguous to the inner impurity region 45 from one side in the second direction Y and a second lattice defect region 62 that linearly extends in the first direction X and that is contiguous to the inner impurity region 45 from the other side in the second direction Y.

The outer contact impurity region 47 on one side in the second direction Y is sandwiched between the first lattice defect region 61 and the epitaxial layer 7 in a plan view. The outer contact impurity region 47 on the other side in the second direction Y is sandwiched between the second lattice defect region 62 and the epitaxial layer 7 in a plan view.

A bottom portion 60a of the lattice defect region 60 includes a pair of curved portions toward the semiconductor substrate 6 and a flat portion that connects the curved portions together. The flat portion of the bottom portion 60a of the lattice defect region 60 is formed so as to be flush with a flat portion of a bottom portion 45a of the inner impurity region 45 and a flat portion of a bottom portion 47a of the outer contact impurity region 47.

Unlike the example of FIG. 21, the flat portion of the bottom portion 60a of the lattice defect region 60 may be placed closer to the first principal surface 3 side than the flat portion of the bottom portion 45a of the inner impurity region 45 and than the flat portion of the bottom portion 47a of the outer contact impurity region 47. On the contrary, the flat portion of the bottom portion 60a of the lattice defect region 60 may be placed closer to the second principal surface 4 side than the flat portion of the bottom portion 45a of the inner impurity region 45 and than the flat portion of the bottom portion 47a of the outer contact impurity region 47.

With the Schottky barrier diode 1R of the second preferred embodiment, the same effect as the Schottky barrier diode 1 of the first preferred embodiment is fulfilled. On the other hand, in a configuration in which the lattice defect region 60 is not provided like the Schottky barrier diode 1 of the first preferred embodiment, there is a case in which a voltage drop by means of the epitaxial layer 7 will become large, and a voltage applied to the p-n junction PJ will become small if the thickness TE of the epitaxial layer 7 is large.

Therefore, it is possible to restrain an electric current I1 flowing to the lattice defect region 60 and is possible to make an electric current I1 smaller than an electric current I2 flowing to the Schottky junction SJ by providing the lattice defect region 60 as in the second preferred embodiment. Thereby, a voltage drop V1 caused by a first nearby part 70, which is placed near the lattice defect region 60, of the epitaxial layer 7 is reduced as shown in FIG. 22A, and becomes smaller than a voltage drop V2 caused by a second nearby part 71, which is placed near the Schottky junction SJ, of the epitaxial layer 7.

Therefore, a voltage drop of a part, which is placed near the inner impurity region 45, of the epitaxial layer 7 also becomes small in the same way as the voltage drop V1 caused by the first nearby part 70. Therefore, it is possible to make a potential difference VP applied to a p-n junction PJ1 formed between the inner impurity region 45 and the epitaxial layer 7 larger than a potential difference VS applied to the Schottky junction SJ. Therefore, it is possible to sufficiently secure a potential difference VP applied to the p-n junction PJ1 formed between the inner impurity region 45 and the epitaxial layer 7. Therefore, it is possible to improve surge withstand capability.

If the distance L between the Schottky junction SJ and the inner impurity region 45 is larger than the thickness TE of the epitaxial layer 7 as shown in FIG. 21B, it is possible to more reliably prevent an electric current from flowing to a part, which is placed between the inner impurity region 55 and the semiconductor substrate 6, of the epitaxial layer 7. The distance L between the Schottky junction SJ and the inner impurity region 45 corresponds to the sum of the width W1 of the outer contact impurity region 47 and the width W2 of the first lattice defect region 61 (width of the second lattice defect region 62).

A region inside a position determined by moving toward the inner impurity region 45 side by the same width as the thickness TE of the epitaxial layer 7 from a boundary portion 73 of the Schottky junction SJ and a p-n junction PJ2 formed between the outer contact impurity region 47 and the epitaxial layer 7 is referred to as an inner region IR, and a region outside the inner region IR is referred to as an outer region OR. In the inner region IR, an electric current flowing to the epitaxial layer 7 is effectively restrained by the lattice defect region 60. If the distance L between the Schottky junction SJ and the inner impurity region 45 is larger than the thickness TE of the epitaxial layer 7, the inner region IR is set at the epitaxial layer 7. In other words, if the distance L between the Schottky junction SJ and the inner impurity region 45 is larger than the thickness TE of the epitaxial layer 7, the first nearby part 70 is placed within the inner region IR.

The preferred embodiment of the present disclosure has been described as above, and yet the present disclosure can be implemented in other modes.

For example, a configuration may be employed in which the conductivity type of each of the semiconductor parts of the Schottky barrier diodes 1 and 1R is inverted. For example, in the Schottky barrier diodes 1 and 1R, the p-type part may be replaced with an n-type, and the n-type part may be replaced with a p-type.

Additionally, the structure of the above-described Schottky electrode 15 (Ti) that contains oxygen is not limited to a discrete product, such as the Schottky barrier diode 1 or 1R, and can be applied to, for example, a composite element in which a transistor, such as MOSFET or IGBT, and a Schottky barrier diode are combined together or can be applied to, for example, a Schottky junction portion formed in LSI or the like in which many circuit elements including a Schottky barrier diode are mounted.

1. A semiconductor device comprising:
a semiconductor layer; and
a Schottky electrode that is formed at a first surface of the semiconductor layer and that forms a Schottky junction portion between the semiconductor layer and the Schottky electrode,
wherein the Schottky electrode has a first portion that is selectively formed near the first surface of the semiconductor layer in a thickness direction of the Schottky electrode and that is made of Ti containing oxygen.

2. The semiconductor device according to claim 1, wherein the Schottky electrode has a second portion that is formed on the first portion and that is made of Ti and N.

3. The semiconductor device according to claim 2, wherein an oxygen concentration near the Schottky junction portion is higher than both an oxygen concentration in the vicinity of an interface between the first portion and the second portion and an average oxygen concentration of the semiconductor layer.

4. The semiconductor device according to claim 1, wherein, when an analysis is made in a first direction from the Schottky electrode toward the semiconductor layer according to a predetermined quantitative-analysis method, an oxygen concentration profile corresponding to an inside of the first portion has a peak at a position closer to a boundary portion between the first portion and the semiconductor layer than a center position of the first portion in the first direction.

5. The semiconductor device according to claim 4, wherein a concentration at the peak of the oxygen concentration profile is not less than 2.0 atm % and not more than 10.0 atm %.

6. The semiconductor device according to claim 1, further comprising an insulation layer that is formed at the first surface of the semiconductor layer and that has an opening from which the first surface is partially exposed,
wherein the Schottky electrode includes a first covering portion that covers the first surface of the semiconductor layer in the opening of the insulation layer and a second covering portion that is formed outside the opening of the insulation layer and that covers the insulation layer, and
the first portion selectively contains oxygen in the first covering portion of the Schottky electrode, and does not contain oxygen in the second covering portion.

7. The semiconductor device according to claim 1, wherein the semiconductor layer does not contain oxygen near the first surface in the Schottky junction portion.

8. The semiconductor device according to claim 1, further comprising a front surface electrode that is formed on the Schottky electrode and that is made of an Al alloy or Al.

9. The semiconductor device according to claim 8, wherein the Al alloy includes at least one among an AlCu alloy, an AlSi alloy, and an AlSiCu alloy.

10. The semiconductor device according to claim 1, wherein
the semiconductor layer includes a first conductivity type semiconductor layer, and
the semiconductor device further comprises a second conductivity type impurity region that is selectively formed at the first surface of the semiconductor layer so as to be contiguous to the Schottky electrode and that makes a p-n junction between the semiconductor layer and the second conductivity type impurity region.

11. The semiconductor device according to claim 10, further comprising a lattice defect region that is selectively formed at the first surface of the semiconductor layer so as to be contiguous to the Schottky electrode and that has lattice defects more than the semiconductor layer,
wherein the impurity region includes a first region formed inside the lattice defect region so as to be contiguous to the lattice defect region.

12. The semiconductor device according to claim 10, wherein the first conductivity type is an n-type, and the second conductivity type is a p-type.

13. The semiconductor device according to claim 1, wherein the semiconductor layer includes an SiC semiconductor layer.

14. A method for manufacturing a semiconductor device, the method comprising:
a step of introducing oxygen into a first surface of the semiconductor layer having the first surface;
a step of forming a Schottky electrode having a first portion made of Ti that is contiguous to the first surface of the semiconductor layer by depositing Ti on the first surface of the semiconductor layer; and
a step of diffusing the oxygen introduced into the semiconductor layer into the first portion of the Schottky electrode by annealing treatment.

15. The method for manufacturing a semiconductor device according to claim 14, further comprising a step of washing the first surface of the semiconductor layer by means of a chemical liquid,
wherein the step of introducing oxygen includes a step of introducing oxygen into the semiconductor layer by irradiating oxygen plasma toward the first surface of the semiconductor layer washed by the chemical liquid.

16. The method for manufacturing a semiconductor device according to claim 14, wherein the step of forming a Schottky electrode includes a step of forming a second portion made of Ti and N on the first portion by additionally depositing Ti in an N₂ atmosphere after the first portion is formed.
